(19) United States
(12) Patent Application Publication
(10) Pub. No.: US 2013/0299711 A1
(43) Pub. Date: Nov. 14, 2013

(54) DETECTION DEVICE, DETECTION SYSTEM, AND METHOD OF MANUFACTURING DETECTION DEVICE

(71) Applicant: CANON KABUSHIKI KAISHA, Tokyo (JP)

(72) Inventors: Chiori Mochizuki, Sagamihara-shi (JP); Minoru Watanabe, Honjo-shi (JP); Keigo Yokoyama, Honjo-shi (JP); Masato Ofuji, Honjo-shi (JP); Jun Kawanabe, Kodama-gun (JP); Kentaro Fujiyoshi, Tokyo (JP); Hiroshi Wayama, Saitama-shi (JP)

(73) Assignee: CANON KABUSHIKI KAISHA, Tokyo (JP)

(21) Appl. No.: 13/887,694

(22) Filed: May 6, 2013

(30) Foreign Application Priority Data
May 8, 2012 (JP) 2012-106882

(51) Int. Cl. H01L 27/146; G01T 1/24

(52) U.S. Cl. CPC H01L 27/14643; H01L 27/14683; G01T 1/24
USPC 250/370.14; 257/292; 438/73

(57) ABSTRACT

A detection device includes conversion elements, each including a first electrode disposed on a substrate, a semiconductor layer disposed on the first electrode, an impurity semiconductor layer disposed on the semiconductor layer and including at least a first region and a second region, and a second electrode disposed on the first region of the impurity semiconductor layer in contact with the impurity semiconductor layer. Sheet resistance in the second region disposed at a position where the impurity semiconductor layer is not contacted with the second electrode is less than sheet resistance in the first region.

### BACKGROUND OF THE INVENTION

1. Field of the Invention

The present application relates to a detection device that is applied to, e.g., an image diagnosis apparatus for medical care, a nondestructive inspection apparatus, and an analysis apparatus using radiation. The present application further relates to a detection system and a method of manufacturing the detection device.

2. Description of the Related Art

Recently, the thin-film semiconductor manufacturing technology has been employed to manufacture a detection device including an array of pixels (pixel array), which is a combination of switch elements, e.g., thin-film transistors (TFTs), and conversion elements, e.g., photodiodes, for converting radiation or light to electric charges.

Each of pixels in related-art detection devices disclosed in Japanese Patent Laid-Open No. 2004-296654 and No. 2007-059887 includes a conversion element including a first electrode disposed on a substrate, a second electrode disposed above the first electrode, a semiconductor layer disposed between the first electrode and the second electrode, and an impurity semiconductor layer disposed between the second electrode and the semiconductor layer. The first electrode, the second electrode, the semiconductor layer, and the impurity semiconductor layer are each separated per conversion element, and the second electrode is disposed on the inner side than a region where the impurity semiconductor layer is disposed.

In the structure disclosed in Japanese Patent Laid-Open No. 2004-296654 and No. 2007-059887, however, an uncovered region not covered with the second electrode exists in the impurity semiconductor layer, particularly, in the impurity semiconductor layer around the second electrode. Because the impurity semiconductor layer has much higher specific resistance than the second electrode, an electric field tends to be less efficiently applied to a region of the semiconductor layer, which contacts with the uncovered region of the impurity semiconductor layer, in comparison with the case where the second electrode is disposed over the entire impurity semiconductor layer. Even if an electric field is sufficiently applied to the relevant region of the semiconductor layer, when collecting electric charges generated in the relevant region of the semiconductor layer to the second electrode, a distance through which the electric charges generated in the relevant region of the semiconductor layer are moved in the impurity semiconductor layer is longer than a distance through which electric charges generated in a region of the semiconductor layer positioned just under the second electrode are moved. Therefore, a time required to collect the electric charges generated in the above-mentioned relevant region is prolonged and a collection speed of the electric charges is reduced. Thus, there is a possibility that response characteristics, e.g., sensitivity and an operation speed, of the detection device may degrade in comparison with those obtained in the case where the second electrode is disposed over the entire impurity semiconductor layer.

With the view of solving the above-described problems in the related art, the present disclosure provides a detection device that has good response characteristics as a result of suppressing reduction of the response characteristics.

### SUMMARY OF THE INVENTION

According to an embodiment as disclosed herein, there is provided a detection device including conversion elements each of which includes a first electrode disposed on a substrate, a semiconductor layer disposed on the first electrode, an impurity semiconductor layer disposed on the semiconductor layer and including at least a first region and a second region, and a second electrode disposed on the first region of the impurity semiconductor layer in contact with the impurity semiconductor layer, wherein sheet resistance in the second region disposed at a position where the impurity semiconductor layer is not contacted with the second electrode is less than sheet resistance in the first region.

According to another embodiment as disclosed herein, there is provided a method of manufacturing a detection device including conversion elements each of which includes a first electrode disposed on a substrate, a semiconductor layer disposed on the first electrode, an impurity semiconductor layer disposed on the semiconductor layer, and a second electrode disposed on the impurity semiconductor layer in contact with the impurity semiconductor layer, the method including the steps of successively forming, on the first electrode, a semiconductor film becoming the semiconductor layer, and an impurity semiconductor film including a first region and a second region different from the first region, the impurity semiconductor film becoming the impurity semiconductor layer, in mentioned order, forming, on the impurity semiconductor film, an electroconductive film becoming the second electrode, and removing at least a part of a region of the electroconductive film, the region contacting with the second electrode, thereby forming the second electrode, and reducing sheet resistance in the second region to be lower than sheet resistance in the first region.

With the embodiment of the present disclosure, the detection device capable of suppressing reduction of the response characteristics and having good response characteristics can be provided.

Further features of the present invention will become apparent from the following description of exemplary embodiments with reference to the attached drawings.

### BRIEF DESCRIPTION OF THE DRAWINGS

FIG. 1A is a schematic plan view of one of pixels in a detection device according to a first embodiment, FIG. 1B is a schematic sectional view taken along a line IB-IB in FIG. 1A, and FIG. 1C is a schematic sectional view taken along a line IC-IC in FIG. 1A.

FIGS. 2A, 2C and 2E illustrate mask patterns to explain a method of manufacturing the detection device according to the first embodiment, and FIGS. 2B, 2D and 2F are schematic sectional views in relevant steps, each taken along a line corresponding to the IB-IB line in FIG. 1A.

FIGS. 3A, 3C and 3E illustrate mask patterns to explain the method of manufacturing the detection device according to the first embodiment, and FIGS. 3B, 3D and 3F are schematic sectional views in relevant steps, each taken along a line corresponding to the IB-IB line in FIG. 1A.

FIGS. 4A, 4D and 4G illustrate mask patterns to explain the method of manufacturing the detection device according to the first embodiment, and FIGS. 4B, 4C, 4E, 4F, 4H and 4I are schematic sectional views in relevant steps, each taken along a line corresponding to the IB-IB line in FIG. 1A.

FIG. 5 is a schematic equivalent circuit diagram of the detection device.

FIGS. 6A and 6B are schematic sectional views of one of pixels in a detection device according to a second embodiment.

FIGS. 7A, 7C and 7E illustrate mask patterns to explain a method of manufacturing the detection device according to the second embodiment, and FIGS. 7B, 7D and 7F are schematic sectional views in relevant steps, each taken along a line corresponding to the IB-IB line in FIG. 1A.

FIGS. 8A and 8B are schematic sectional views of one of pixels in a detection device according to a third embodiment.

FIGS. 9A, 9C and 9E illustrate mask patterns to explain a method of manufacturing the detection device according to the third embodiment, and FIGS. 9B, 9D and 9F are schematic sectional views in relevant steps, each taken along a line corresponding to the IB-IB line in FIG. 1A.

FIGS. 10A and 10B are schematic sectional views of one of pixels in a detection device according to a fourth embodiment.

FIGS. 11A, 11C and 11E illustrate mask patterns to explain a method of manufacturing the detection device according to the fourth embodiment, and FIGS. 11B, 11D and 11F are schematic sectional views in relevant steps, each taken along a line corresponding to the IB-IB line in FIG. 1A.

FIGS. 12A and 12B are schematic sectional views of one of pixels in a detection device according to a fifth embodiment.

FIGS. 13A and 13B are schematic sectional views to explain a method of manufacturing the detection device according to the fifth embodiment.

FIG. 14 is a conceptual illustration of a radiation detection system using the detection device according to the embodiment of the present disclosure.

### DESCRIPTION OF THE EMBODIMENTS

Embodiments of the present disclosure will be described in detail below with reference to the accompanying drawings. It is to be noted that the term “radiation” used in this specification includes not only beams formed by particles (including photons) emitted through radioactive decay, such as an α-ray, a β-ray, and a γ-ray, but also beams having energy comparable to or more than the above-mentioned beams, such as an X-ray, a corpuscular ray, and a cosmic ray.

### First Embodiment

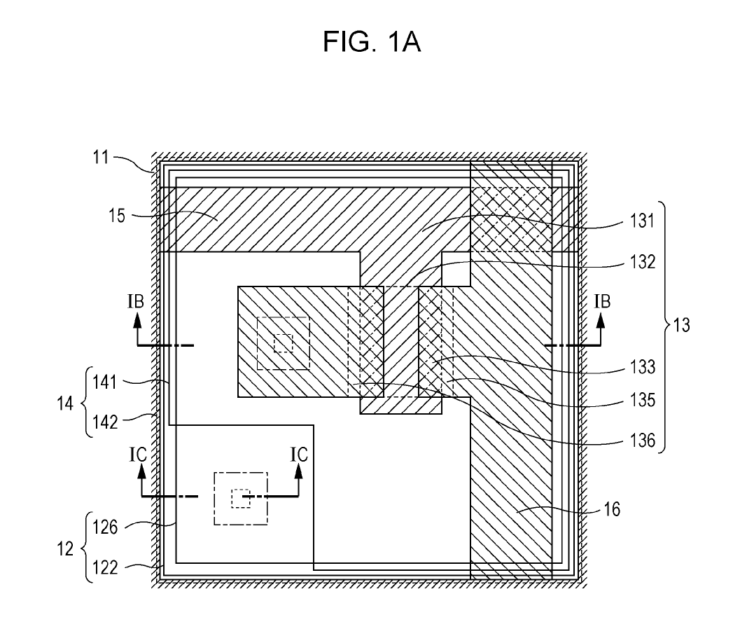

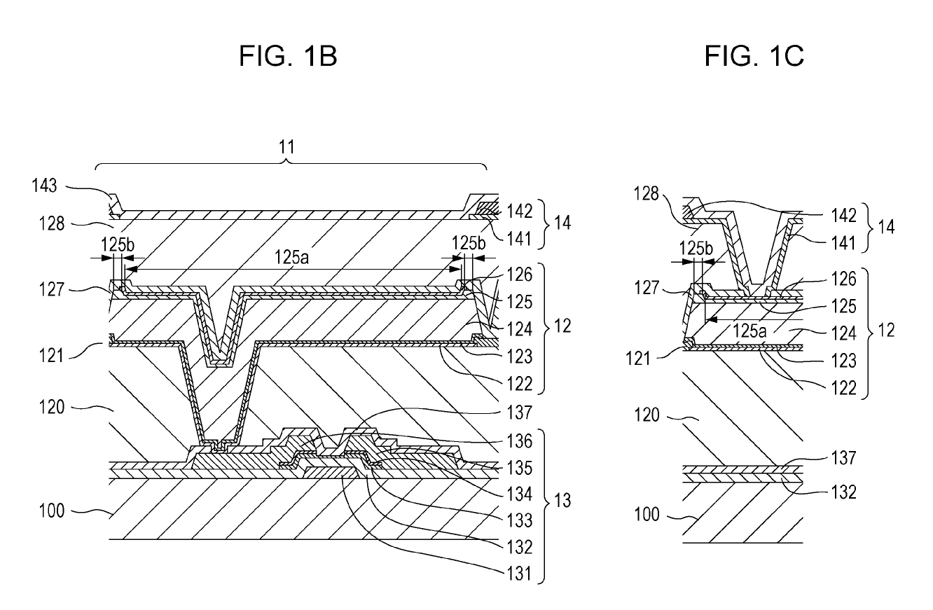

The structure of one pixel in a detection device according to a first embodiment of the present application is first described with reference to FIG. 1A to 1C. FIG. 1A is a schematic plan view of one of the pixels. In FIG. 1A, insulating layers and a semiconductor layer of a conversion element are omitted for simplification of the drawing. FIG. 1B is a schematic sectional view taken along a line IB-IB in FIG. 1A, and FIG. 1C is a schematic sectional view taken along a line IB-IB in FIG. 1A. The insulating layers and the semiconductor layer of the conversion element, omitted in FIG. 1A, are illustrated in FIGS. 1B and 1C.

One pixel 11 in the detection device according to the first embodiment of the present disclosure includes a conversion element 12 for converting radiation or light to electric charges, and a TFT (thin-film transistor) 13 serving as a switch element that transfers an electric signal corresponding to the electric charges converted by the conversion element 12. The conversion element 12 may be constituted as an indirect conversion element including a photoelectric conversion element and a wavelength converter for converting radiation to light in a wavelength band sensible by the photoelectric conversion element, or as a direct conversion element for directly converting radiation to electric charges. In this embodiment, a PIN photodiode made of primarily amorphous silicon is used as a photodiode that is one type of photoelectric conversion elements. The conversion element 12 is stacked above the TFT 113, which is disposed on an insulating substrate 100, e.g., a glass substrate, with a passivation layer 137 and a first interlayer insulating layer 120 interposed between the conversion element 12 and the TFT 113.

The TFT 13 includes a control electrode 131, a gate insulating layer 132, a semiconductor layer 133, an impurity semiconductor layer 134 having a higher impurity concentration than the semiconductor layer 133, a first main electrode 135, and a second main electrode 136, which are successively formed on the substrate 100 in the mentioned order from the substrate side. The control electrode 131 serves as a gate electrode of the TFT 113. The first main electrode 135 serves as one of a source electrode and a drain electrode of the TFT 113. The second main electrode 136 serves as the other of the source electrode and the drain electrode of the TFT 113. Partial regions of the impurity semiconductor layer 134 are contacted with the first main electrode 135 and the second main electrode 136, respectively. A region of the semiconductor layer 133, which is positioned between regions thereof contacting respectively with the above-mentioned partial regions of the impurity semiconductor layer 134, serves as a channel region of the TFT 113. The control electrode 131 is electrically connected to a control wiring 15. The first main electrode 135 is electrically connected to a signal wiring 16, and the second main electrode 136 is electrically connected to a first electrode 122 of the conversion element 12. In this embodiment, the first main electrode 135 and the signal wiring 16 are integrally constituted by the same electroconductive layer, and the first main electrode 135 is a part of the signal wiring 16. Furthermore, in this embodiment, the control electrode 131 and the control wiring 15 are integrally constituted by the same electroconductive layer, and the control electrode 131 is a part of the control wiring 15. The passivation layer 137 is made of an inorganic insulating material, e.g., silicon oxide or silicon nitride, and is disposed to cover the TFT 13, the control wiring 15, and the signal wiring 16. While, in this embodiment, an inverted-staggered TFT using the semiconductor layer 133 and the impurity semiconductor layer 134, each made of primarily amorphous silicon, is used as the switch element, the switch element used in the present application is not limited to that type. As another example, a staggered TFT made of primarily polycrystalline silicon, an organic TFT, or an oxide TFT may also be used.

The first interlayer insulating layer 120 is disposed between the substrate 100 and the plural first electrodes 122 (described later) to cover the plural TFTs 13, and it has contact holes. The first electrode 122 of the conversion element 12 and the second main electrode 136 of the TFT 13 are electrically connected to each other in the contact hole formed in the first interlayer insulating layer 120. The first interlayer insulating layer 120 is advantageously made of an organic insulating material, which can be formed thick, to reduce a parasitic capacity between the conversion element 12 and each of the TFT 13, the control wiring 15, and the signal wiring 16.

The conversion element 12 includes the first electrode 122, an impurity semiconductor layer 123 of first conductivity type, a semiconductor layer 124, an impurity semiconductor layer 125 of second conductivity type, and the second electrode 126, which are successively formed on the first interlayer insulating layer 120 in the mentioned order from the first interlayer insulating layer side. Herein, the semiconductor layer 124 disposed above the first electrode 122 and between the first electrode 122 and the second electrode 126 is desirably an intrinsic semiconductor. The impurity semiconductor layer 123 of first conductivity type disposed on the first electrode 122 and between the first electrode 122 and the semiconductor layer 124 exhibits a polarity of first conductivity type, and it contains impurities of first conductivity type at a higher concentration than the semiconductor layer 124 and the impurity semiconductor layer 125 of second conductivity type. The impurity semiconductor layer 125 of second conductivity type disposed on the semiconductor layer 124 and between the semiconductor layer 124 and the second electrode 126 exhibits a polarity of second conductivity type opposite to the first conductivity type, and it contains impurities of second conductivity type at a higher concentration than the impurity semiconductor layer 123 of first conductivity type and the semiconductor layer 124. The first conductivity type and the second conductivity type are conductivity types differing in polarity from each other. For example, when the first conductivity type is n-type, the second conductivity type is p-type. An electrode wiring 14 (described later) is electrically connected to the second electrode 126 that is disposed on the impurity semiconductor layer 125 of second conductivity type to be contacted with the impurity semiconductor layer 125. The first electrode 122 is electrically connected to the second main electrode 136 of the TFT 13 in the contact hole formed in the first interlayer insulating layer 120. While this embodiment employs the photodiode including the impurity semiconductor layer 123 of first conductivity type, the semiconductor layer 124, and the impurity semiconductor layer 125 of second conductivity type, those layers being made of primarily amorphous silicon, the photodiode usable in the present disclosure is not limited to that type. As another example, an element of directly converting radiation to electric charges may also be used. Such an element may include the impurity semiconductor layer 123 of first conductivity type, the semiconductor layer 124, and the impurity semiconductor layer 125 of second conductivity type, those layers being made of primarily amorphous selenium. The first electrode 122 and the second electrode 126 of the conversion element 12 are each made of a transparent electroconductive oxide, e.g., light-transmissive ITO. However, the first electrode 122 may be made of a metallic material. In particular, when the conversion element 12 is an indirect conversion element including a photoelectric conversion element and a wavelength converter, the transparent electroconductive oxide, e.g., light-transmissive ITO, is used for the second electrode 126 that is an electrode positioned on the wavelength converter side. On the other hand, the first electrode 122 positioned farther away from the wavelength converter than the second electrode 126 may be made of an electrical conductor made of Al and having low light transmissivity.

In the present application, the impurity semiconductor layer 125 of second conductivity type has a first region 125a and a second region 125b different from the first region 125a. The second region 125b is disposed at a position where the second region 125b does not contact with the second electrode 126. In other words, the second region 125b is a region that is not covered with the second electrode 126 and that is positioned around the first region 125a. Sheet resistance in the second region 125b, i.e., second sheet resistance, is set to be lower than that in the first region 125a, i.e., first sheet resistance. Generally, sheet resistance of an impurity semiconductor layer is determined depending on the concentration of impurities therein and the thickness thereof. In the photoelectric conversion element used in the indirect conversion element described above, light transmissivity of the impurity semiconductor layer reduces as the sheet resistance lowers. In that photoelectric conversion element, therefore, the sheet resistance cannot be lowered to a larger extent than a certain level in a region of the impurity semiconductor layer 125, the region contacting with the second electrode 126. To cope with such a problem, in the present disclosure, the sheet resistance in the second region 125b, which is positioned not in contact with the second electrode 126, is set to be lower than that in the first region 125a positioned in contact with the second electrode 126. As a result, in the photoelectric conversion element used in the indirect conversion element described above, reduction of the light transmissivity of the first region 125a can be suppressed, and reduction of the sensitivity can also be suppressed. Moreover, electric charges generated in a region of the semiconductor layer 124, the region contacting with the second region 125b, can be more quickly moved up to the first region 125a in contact with the second electrode 126, and reduction of response characteristics can be suppressed. In this embodiment illustrated in FIGS. 1B and 1C, the second region 125b has a larger thickness than the first region 125a such that the second sheet resistance is lower than the first sheet resistance. Taking a process margin into consideration, in this embodiment, the second electrode 126 is disposed in contact with not only the thinner region (first region 125a) of the impurity semiconductor layer 125, but also a part of the thicker region (second region 125b) of the impurity semiconductor layer 125. When the second electrode 126 can be formed with high accuracy, the second electrode 126 may be disposed in contact with only the thinner region of the impurity semiconductor layer 125.

It is here advantageous that the sheet resistance in the second region 125b of the impurity semiconductor layer 125 satisfies the following formula;

4×Rs(D/P)≦Ron

where a width of the second region 125b of the impurity semiconductor layer 125 is D (μm), a width of the conversion element 12 is P (μm), the sheet resistance in the second region 125b, i.e., the second sheet resistance, is Rs (Ω), and on-resistance of the TFT 13 is Ron (Ω).

While, in this embodiment, the second region 125b is positioned in a part of the impurity semiconductor layer 125 outside an orthographic projection of the second electrode 126, the present disclosure is not limited to such an arrangement. For example, the second electrode 126 may have a comb-like shape, and the second region 125b may be positioned in a part of the impurity semiconductor layer 125 not coincident with each orthographic projection of the comb-like second electrode 126.

Between adjacent two of the plural first electrodes 122 on the first interlayer insulating layer 120, an insulating member (layer) 121 made of an inorganic insulating material is disposed in contact with the first interlayer insulating layer 120. Thus, the first electrode 122 and the insulating member 121 are disposed on the first interlayer insulating layer 120 to cover the first interlayer insulating layer 120. Accordingly, when an impurity semiconductor film becoming the impurity semiconductor layer 123 is formed, the surface of the first interlayer insulating layer 120 is not exposed and mixing of an organic insulating material into the impurity semiconductor layer 123 can be reduced. Moreover, in this embodiment, the impurity semiconductor layer 123, the semiconductor layer 124, and the impurity semiconductor layer 125 are separated for each pixel above the insulating member 121. In a dry etching step for that separation, since the insulating member 121 serves as an etching stop layer, the first interlayer insulating layer 120 is avoided from being exposed to species used in the dry etching, and the surrounding layers can be prevented from being contaminated by the organic insulating material.

The passivation layer 127 and a second interlayer insulating layer 128 are disposed to cover the conversion element 12. The passivation layer 127 is made of an inorganic insulating material, e.g., silicon oxide or silicon nitride, and it covers the conversion element 12 and the insulating member 121. The second interlayer insulating layer 128 is disposed between the second electrode 126 and the electrode wiring 14 to cover the passivation layer 127. The passivation layer 127 and the second interlayer insulating layer 128 have contact holes. The second electrode 126 of the conversion element 12 and the electrode wiring 14 are electrically connected to each other in the contact holes formed in the passivation layer 127 and the second interlayer insulating layer 128. The second interlayer insulating layer 128 is advantageously made of an organic insulating material, which can be formed thick, to reduce a parasitic capacity between the conversion element 12 and the electrode wiring 14.

The electrode wiring 14 includes a first electroconductive layer 141 made of a transparent electroconductive oxide and disposed on the second interlayer insulating layer 128, and a second electroconductive layer 142 made of a metallic material and disposed on the first electroconductive layer 141. The first electroconductive layer 141 is connected to the second electrode 126 of the conversion element 12 in the contact holes formed in the passivation layer 127 and the second interlayer insulating layer 128. The second electroconductive layer 142 is disposed on the first electroconductive layer 141 such that an orthographic projection of the second electroconductive layer 142 is positioned between the two first electrodes 122 of the two conversion elements 12 adjacent to each other.

A passivation layer 143 made of an inorganic insulating material, e.g., silicon oxide or silicon nitride, is disposed to cover the electrode wiring 14.

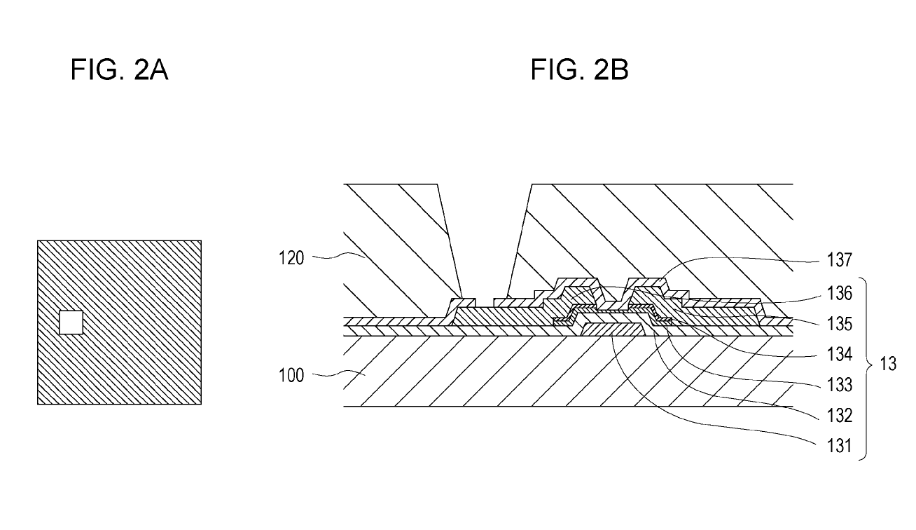

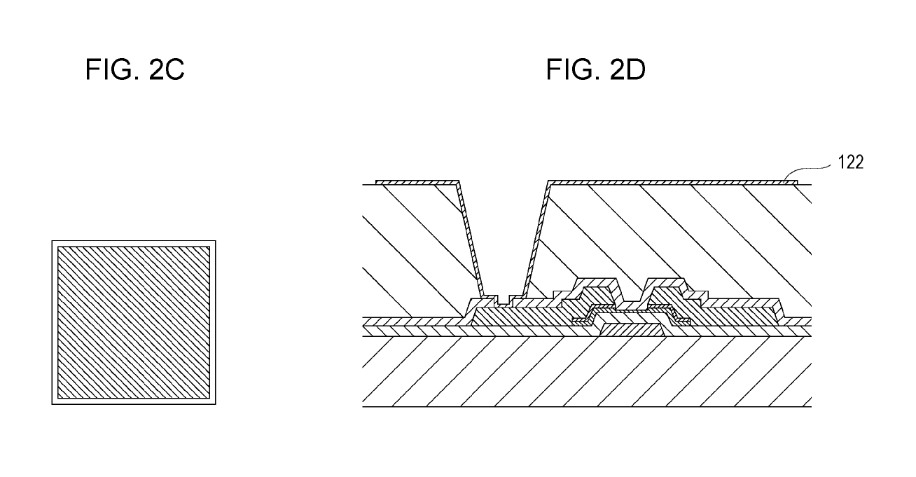

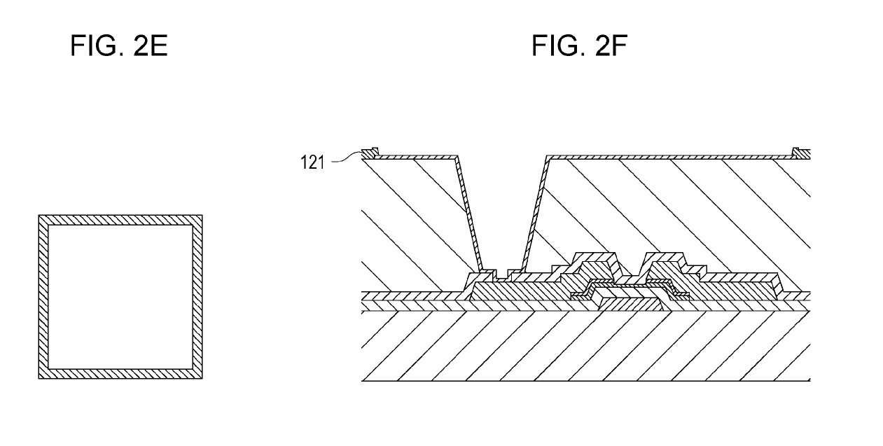

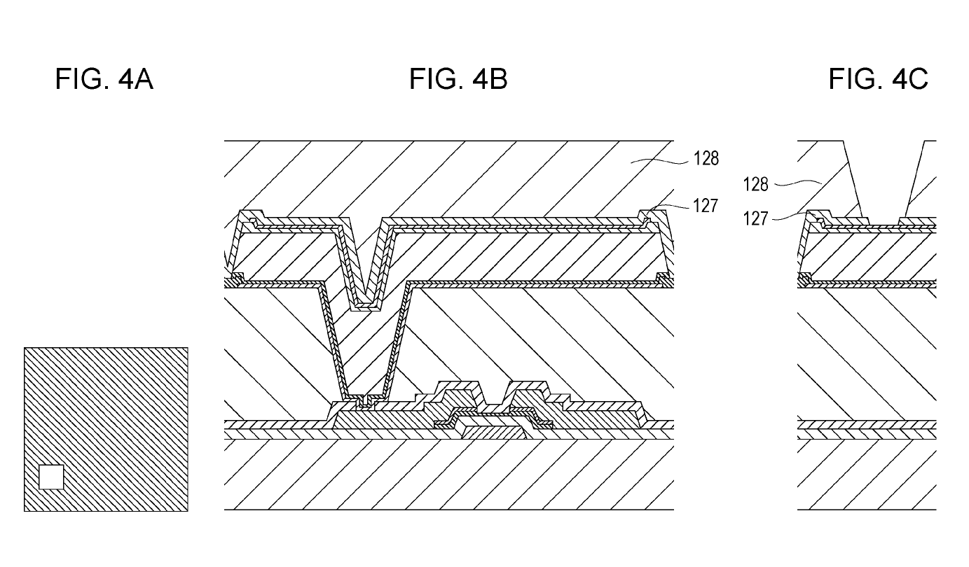

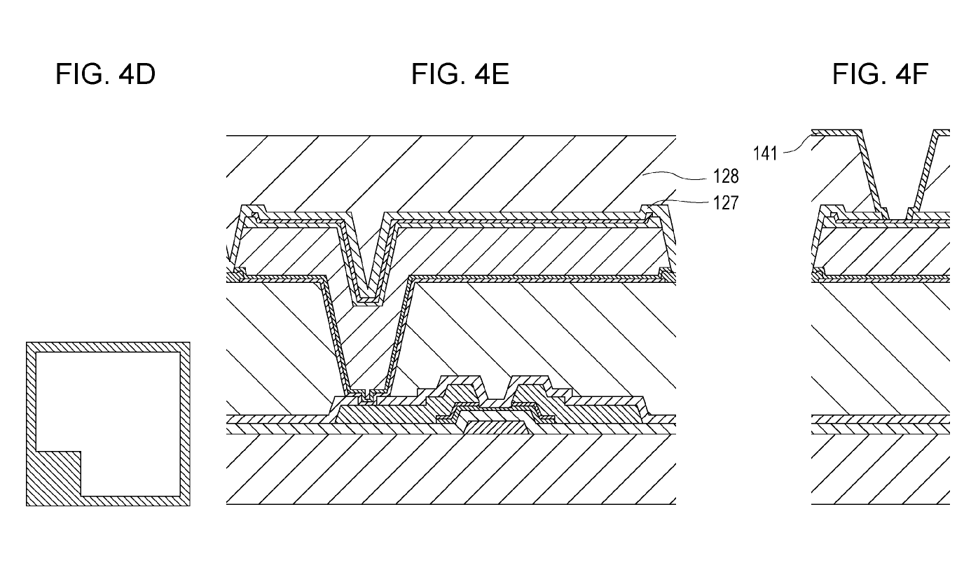

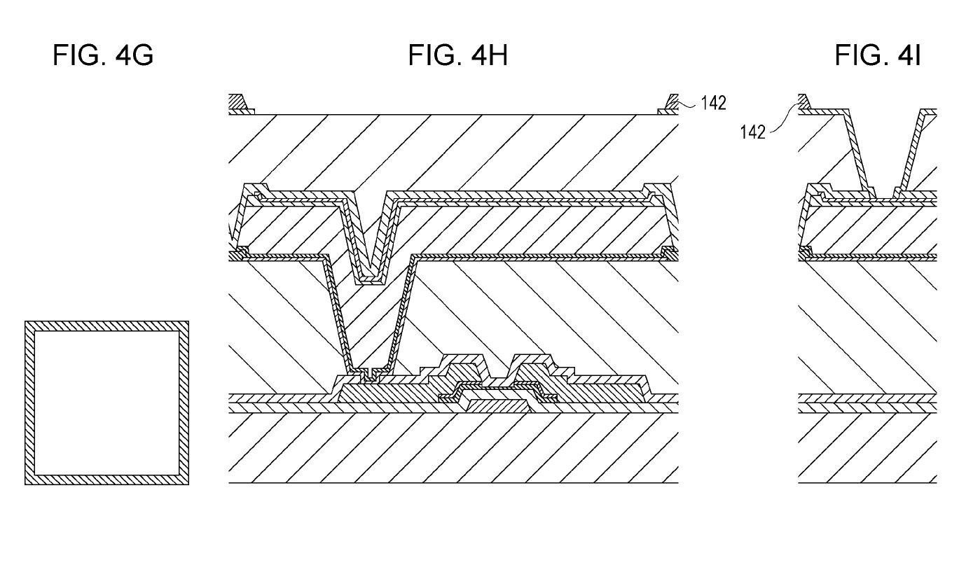

A method of manufacturing the detection device according to the first embodiment of the present application will be described below with reference to FIGS. 2A to 4I. In particular, a process subsequent to a step of forming the contact hole in the first interlayer insulating layer 120 is described in detail with reference to mask patterns and sectional views during the process. FIGS. 2A, 2C and 2E, FIGS. 3A, 3C and 3E, and FIGS. 4A, 4D and 4G are schematic plan views of the mask patterns for photomasks (masks) used in relevant steps. FIGS. 2B, 2D and 2F, FIGS. 3B, 3D and 3F, and FIGS. 4B, 4E and 4H are schematic sectional views in relevant steps, each taken along a line corresponding to the line IB-IB in FIG. 1A. FIGS. 4C, 4F and 4I are schematic sectional views in relevant steps, each taken along a line corresponding to the line IC-IC in FIG. 1A.

The plural TFTs 13 are disposed on the insulating substrate 100, and a protective layer 137 is disposed to cover the plural TFTs 13. A contact hole is formed by etching in the protective layer 137 in its portion on the second main electrode 136 where the second main electrode 136 is electrically connected to the photodiode. In a step illustrated in FIG. 2B, an acrylic resin, i.e., an organic insulating material having photosensitivity, is formed as an interlayer insulating film to cover the TFTs 13 and the protective layer 137 by employing a coating device, e.g., a spinner. A polyimide resin or the like is also usable as the organic insulating material having photosensitivity. The first interlayer insulating layer 120 having the contact hole above the second main electrode 136 is then formed through an exposure and development process with the use of the mask illustrated in FIG. 2A.

In a step illustrated in FIG. 2D, an electroconductive film, e.g., an amorphous transparent electroconductive oxide film made of ITO, is formed by sputtering to cover the second main electrode 136 and the first interlayer insulating layer 120. Then, the first electrode 122 of the conversion element 12 is formed by removing a part of the transparent electroconductive oxide film by wet etching using the mask illustrated in FIG. 2C, and polycrystallizing the transparent electroconductive oxide film by annealing.

In a step illustrated in FIG. 2F, an insulating film made of an inorganic insulating material, e.g., a film of silicon nitride, is formed by plasma CVD to cover the first interlayer insulating layer 120 and the first electrode 122. Then, the insulating member 121 is formed between the pixels by etching the above-mentioned insulating film with the use of the mask illustrated in FIG. 2E. As a result, the surface of the first interlayer insulating layer 120 is covered with the insulating member 121 and the first electrode 122.

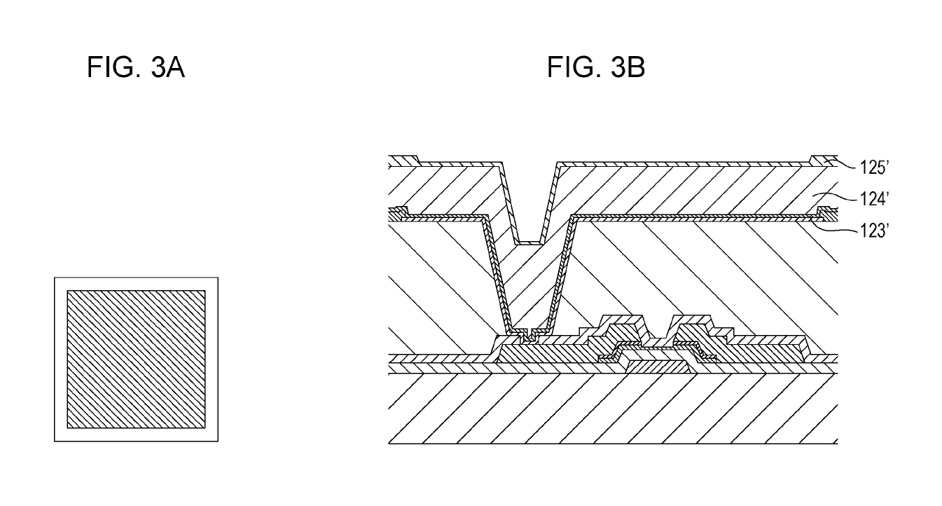

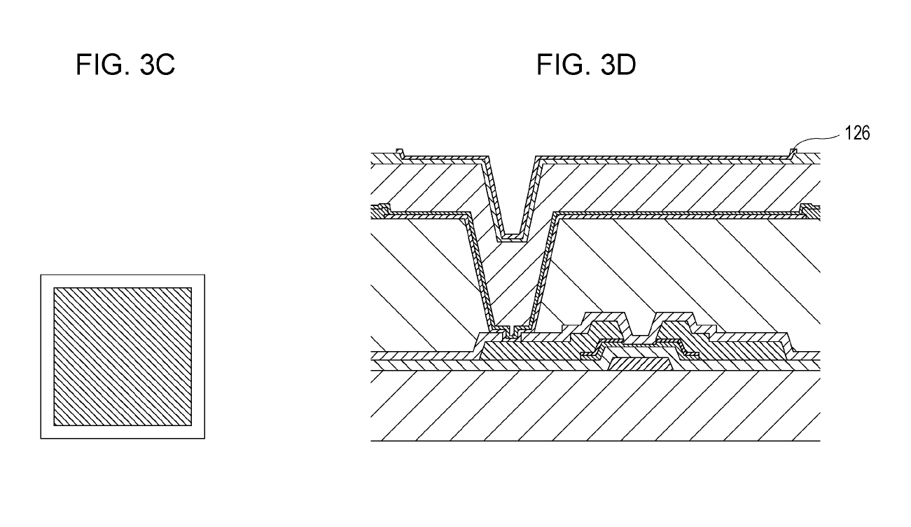

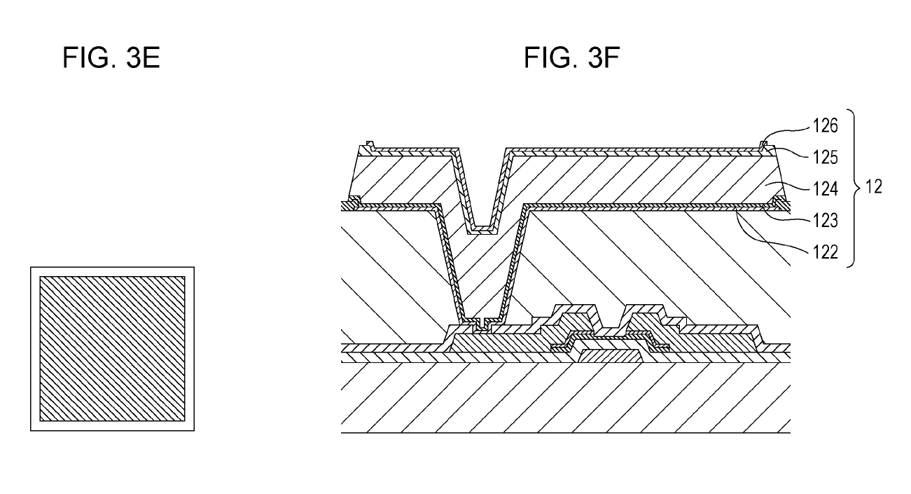

In a step illustrated in FIG. 3B, an amorphous silicon film containing a pentavalent element, e.g., phosphorous, mixed therein as an impurity is formed as an impurity semiconductor film 123′ of first conductivity type by plasma CVD to cover the insulating member 121 and the first electrode 122. Then, a semiconductor film 124′ made of an amorphous silicon film and an amorphous silicon film containing a trivalent element, e.g., boron, mixed therein as an impurity and serving as an impurity semiconductor film 125′ of second conductivity type are successively formed in the mentioned order by plasma CVD. Herein, the impurity semiconductor film 125′ of second conductivity type is formed in the same thickness as that of the second region 125b in FIG. 1B. The above-described step illustrated in FIG. 3B is called a film forming step. Since an entire region of the impurity semiconductor film 125′ is formed under the same conditions, the concentration of impurities in the impurity semiconductor film 125′ is regarded to be uniform over the entire region. Then, a region of the impurity semiconductor film 125′ of second conductivity type, becoming a first region thereof (corresponding to the above-described first region 125a), is partly removed and thinned with the use of the mask illustrated in FIG. 3A such that the relevant region has the same thickness as that of the first region 125a in FIG. 1B. Such a step is called a film thinning step. With the film thinning step, the first region and a second region (corresponding to the above-described second region 125b), which is thicker than the first region and which has lower sheet resistance than the first region, can be formed in the impurity semiconductor film 125′ becoming the impurity semiconductor layer 125.

In a step illustrated in FIG. 3D, an electroconductive film, e.g., a transparent electroconductive oxide film, is formed by sputtering to cover the impurity semiconductor film 125′ of second conductivity type. Then, the transparent electroconductive oxide film is partly removed by wet etching using the mask illustrated in FIG. 3C, thereby forming the second electrode 126. Such a step is called a second electrode forming step. The second electrode 126 requires to be formed just on the first region of the impurity semiconductor film 125′, which has been thinned in the film thinning step. In this embodiment, however, the second electrode 126 is formed to be contacted with a part of the second region of the impurity semiconductor film 125′, which has not been thinned in the film thinning step, in consideration of a process margin.

In a step illustrated in FIG. 3F, the impurity semiconductor film 125′ of second conductivity type, the semiconductor film 124′, and the impurity semiconductor film 123′ of first conductivity type are each partly removed by dry etching using the mask illustrated in FIG. 3E. With that dry etching, an array of conversion elements 12 is separated for each pixel. As a result, the impurity semiconductor layer 125, the semiconductor layer 124, the impurity semiconductor layer 123, and the second electrode 126 are formed on each of the plural first electrodes 122. The above-described pixel separation by the dry etching is effectuated on the insulating member 121. Accordingly, the insulating member 121 functions as an etching stop layer, whereby the first interlayer insulating layer 120 is avoided from being exposed to species used in the dry etching and the surrounding layers can be prevented from being contaminated by the organic insulating material. It is to be noted that, in this embodiment, the step illustrated in FIG. 3F is performed by employing a mask different from the mask, which has been used in the second electrode forming step. If the step illustrated in FIG. 3F is performed by employing the mask having been used in the second electrode forming step as it is, an end of the impurity semiconductor layer 125 is positioned on the inner side than an end of the second electrode 126. In such a case, there is a risk that the passivation layer 127 (described later) may not be formed to fully cover the end of the impurity semiconductor layer 125. For that reason, the step illustrated in FIG. 3F is performed by employing a mask different from the mask, which has been used in the second electrode forming step.

In a step illustrated in FIGS. 4B and 4C, an insulating film made of an inorganic insulating material, e.g., silicon nitride is formed by plasma CVD to cover the conversion element 12 and the insulating member 121. Then, an acrylic resin, i.e., an organic insulating material having photosensitivity, is formed as an interlayer insulating layer to cover the insulating film. The second interlayer insulating layer 128 and the passivation layer 127 having contact holes above the second electrode 126, as illustrated in FIG. 4C, are formed with the use of the mask illustrated in FIG. 4A.

In a step illustrated in FIGS. 4E and 4F, a transparent electroconductive oxide film is formed by sputtering to cover the second interlayer insulating layer 128 and the second electrode 126. Then, the first electroconductive layer 141 is formed by wet-etching the transparent electroconductive oxide film with the use of the mask illustrated in FIG. 4D.

In a step illustrated in FIGS. 4H and 4I, a metal film made of, e.g., Al is formed by sputtering to cover the first electroconductive layer 141 and the second interlayer insulating layer 128. Then, the second electroconductive layer 142 is formed on a part of the first electroconductive layer 141 by wet-etching the metal film with the use of the mask illustrated in FIG. 4G. With the above-mentioned step, the second electroconductive layer 142 and the second electrode 126 of the conversion element 12 are electrically connected to each other through the first electroconductive layer 141. At that time, reduction of an aperture ratio can be suppressed by forming the first electroconductive layer 141 using a transparent electroconductive oxide. Thus, as illustrated in FIGS. 4H and 4I, the electrode wiring 14 made up of the first electroconductive layer 141 and the second electroconductive layer 142 is formed. The structures illustrated in FIGS. 1B and 1C are then obtained by forming the passivation layer 143 to cover the electrode wiring 14 and the second interlayer insulating layer 128.

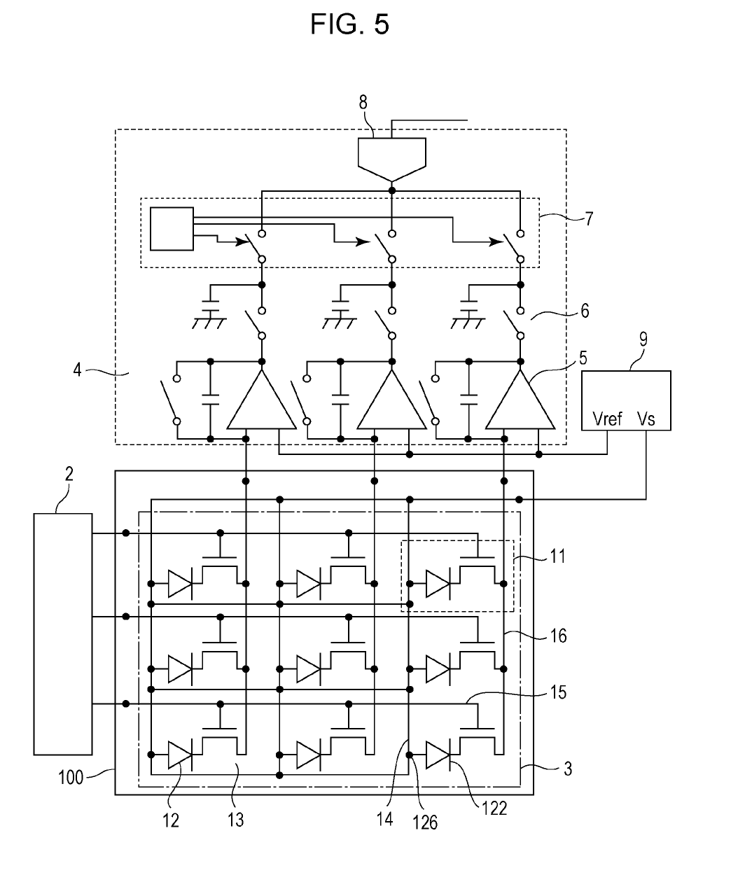

An equivalent circuit of the detection device according to the first embodiment of the present disclosure will be described below with reference to FIG. 5. While FIG. 5 illustrates an equivalent circuit diagram of 3 rows×3 columns for simplification of the description, the present disclosure is not limited to such a configuration. The detection device includes a pixel array of n rows×m columns (n and m are each a natural number equal to or more than 2). In the detection device according to this embodiment, a conversion section 3 including a plurality of pixels 11 arrayed in each of a row direction and a column direction is disposed on the surface of the substrate 100. Each pixel 11 includes the conversion element 12 for converting radiation or light to electric charges, and the TFT 13 for outputting an electric signal corresponding to the electric charges generated by the conversion element 12. In this embodiment, since a PIN photodiode is used as the conversion element 12, a scintillator (not illustrated) for wavelength conversion from radiation to visible light may be disposed on the surface of the conversion element 12 on the side closer to the second electrode 126. The electrode wiring 14 is connected in common to the second electrodes 126 of the plural conversion elements 12. The control wiring 15 is connected in common to the control electrodes 131 of the plural TFTs 13 arrayed in the row direction, and is electrically connected to a drive circuit 2. With the drive circuit 2 successively or simultaneously supplying drive pulses to the plural control wirings 15 arrayed in the column direction, electric signals from the pixels are output in parallel in units of row to the plural signal wirings 16 that are arrayed in the column direction. Each signal wiring 16 is connected in common to the first main electrodes 135 of the plural TFTs 13 arrayed in the column direction, and is electrically connected to a read circuit 4. The read circuit 4 includes, per the signal wiring 16, an integral amplifier 5 for integrating and amplifying the electric signal from the signal wiring 16, and a sample and hold circuit 6 for sampling and holding the electric signal amplified by and output from the integral amplifier 5. The read circuit 4 further includes a multiplexer 7 for converting the electric signals, which are output in parallel from the plural sample and hold circuits 6, to serial electric signals, and an A/D converter 8 for converting the output electric signals to digital data. A reference potential Vref from a power supply circuit 9 is supplied to a non-inverted input terminal of the integral amplifier 5. Furthermore, the power supply circuit 9 is electrically connected to the electrode wirings 14 arrayed in a grid pattern, and it supplies a bias potential Vs to the second electrode 126 of each conversion element 12.

The operation of the detection device according to this embodiment will be described below. The reference potential Vref is applied to the first electrode 122 of the conversion element 12 through the TFT 13, and the bias potential Vs necessary for separating an electron-hole pair, generated by radiation or visible light, is applied to the second electrode 126. In such a state, the radiation having transmitted through a subject or the visible light corresponding to that radiation enters the conversion element 12 and is converted to electric charges, which are accumulated in the conversion element 12. An electric signal corresponding to the electric charges are output to the signal wiring 16 upon the TFF 13 being brought into a conducted state with a drive pulse applied to the control wiring 15 from the drive circuit 2. The electric signal is then read out as digital data to the exterior by the read circuit 4.

### Second Embodiment

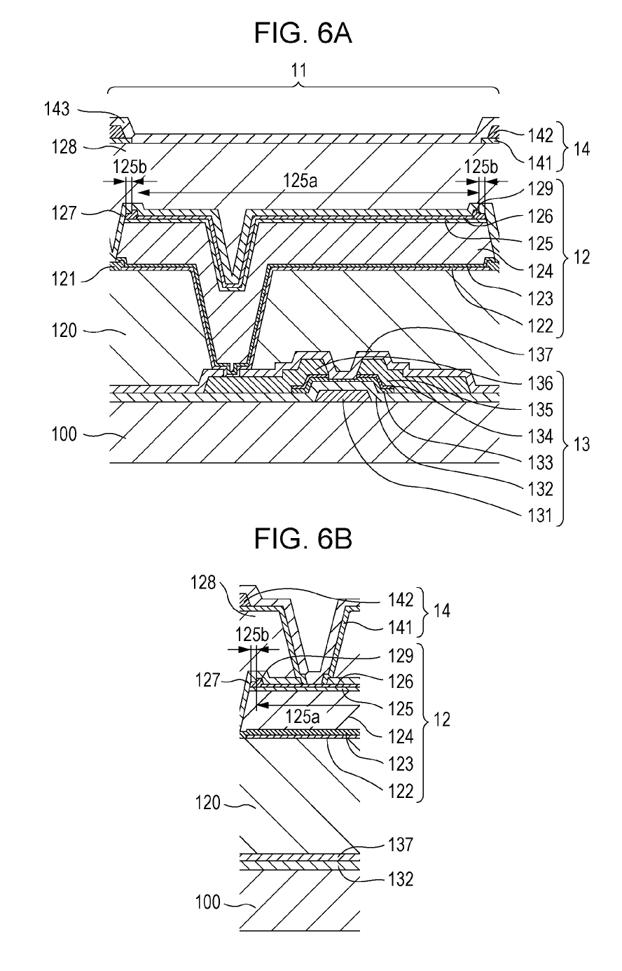

The structure of one pixel in a detection device according to a second embodiment of the present disclosure will be described below with reference to FIGS. 6A and 6B. FIG. 6A is a schematic sectional view taken along a line corresponding to the line IB-IB in FIG. 1A, and FIG. 6B is a schematic sectional view taken along a line corresponding to the line IC-IC in FIG. 1A.

In the second embodiment, as illustrated in FIGS. 6A and 6B, a second region 125b of an impurity semiconductor layer is made up of the impurity semiconductor layer 125 called a first impurity semiconductor layer and an impurity semiconductor layer 129 called a second impurity semiconductor layer. In other words, the second region 125b is formed by stacking a plurality of impurity semiconductor layers. With such a structure, the second region 125b of the impurity semiconductor layer has a larger thickness than the first region 125a thereof. The impurity semiconductor layer 129 is an impurity semiconductor layer of second conductivity type, i.e., having the same conductivity type as the impurity semiconductor layer 125 of second conductivity type. Moreover, the impurity semiconductor layer 129 is disposed on the second electrode 126 such that the second electrode 126 is sandwiched between the impurity semiconductor layer 125 and the impurity semiconductor layer 129.

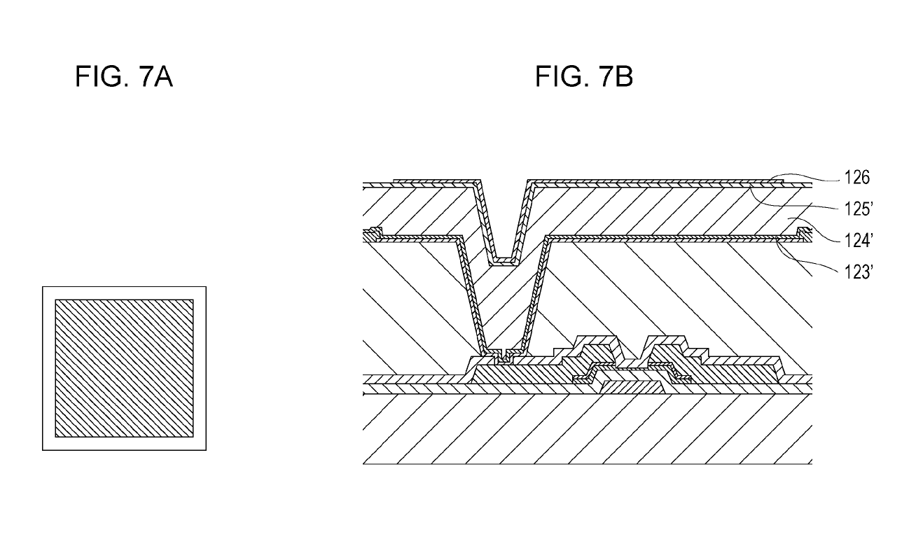

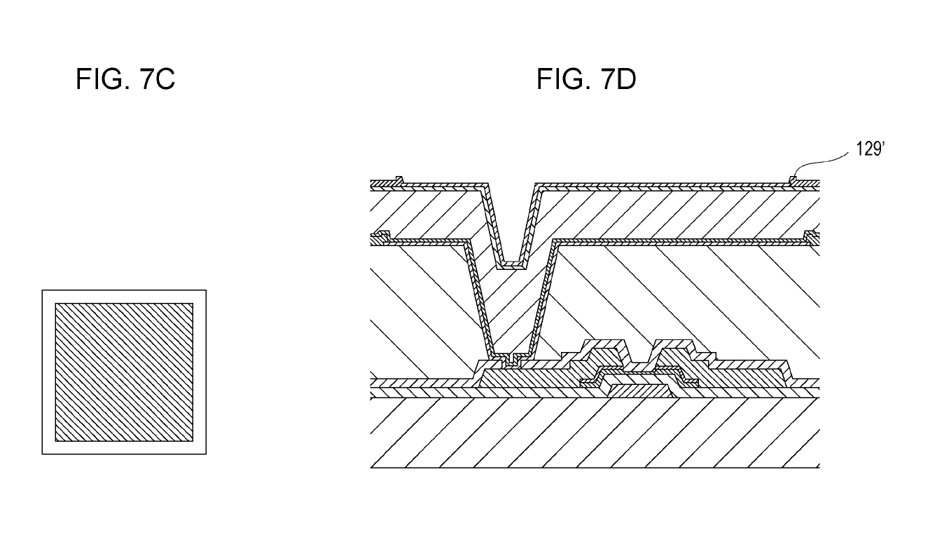

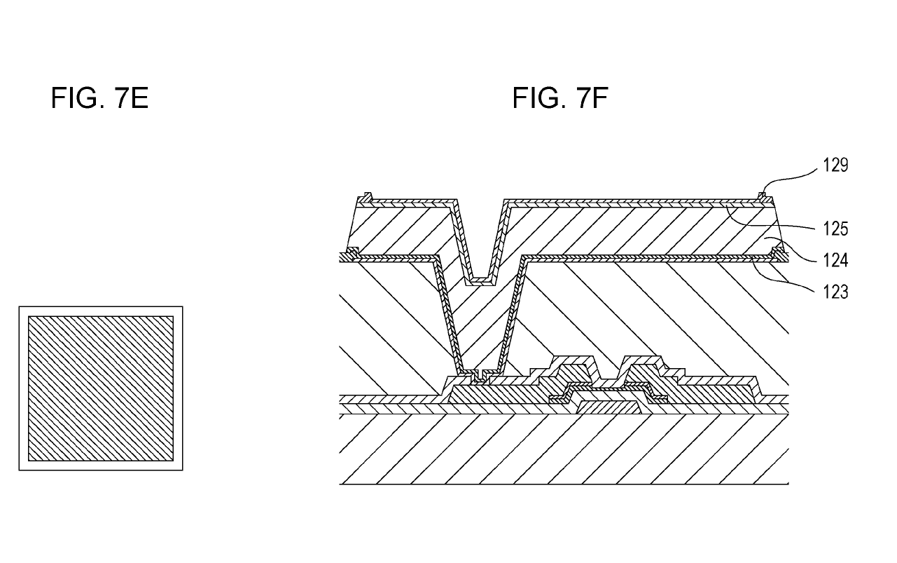

A method of manufacturing the detection device according to the second embodiment of the present disclosure will be described below with reference to FIGS. 7A to 7F. Description of the same steps as those in the first embodiment is omitted here. More specifically, the steps illustrated in FIGS. 2B, 2D and 2F and FIGS. 4B, 4C, 4E, 4F, 4H and 4I are in common to the first embodiment and the second embodiment. FIGS. 7A, 7C and 7E are schematic plan views of the mask patterns for photomasks (masks) used in relevant steps, and FIGS. 7B, 7D and 7F are schematic sectional views in relevant steps, each taken along a line corresponding to the line IB-IB in FIG. 1A.

In a step illustrated in FIG. 7B subsequent to the step illustrated in FIG. 2F, an amorphous silicon film containing a pentavalent element, e.g., phosphorous, mixed therein as an impurity is formed as an impurity semiconductor film 123′ of first conductivity type by plasma CVD to cover the insulating member 121 and the first electrode 122. Then, a semiconductor film 124′ made of an amorphous silicon film and an amorphous silicon film containing a trivalent element, e.g., boron, mixed therein as an impurity and serving as an impurity semiconductor film 125′ of second conductivity type are successively formed in the mentioned order by plasma CVD. Herein, the impurity semiconductor film 125′ corresponds to a first impurity semiconductor film, and the above-described step illustrated in FIG. 7B is called a film forming step. At that time, the impurity semiconductor film 125′ is formed in the same thickness as that of the first region 125a in FIG. 6A. Then, an electroconductive film, e.g., a transparent electroconductive oxide film, is formed by sputtering to cover the impurity semiconductor film 125′ of second conductivity type. The transparent electroconductive oxide film is partly removed by wet etching using the mask illustrated in FIG. 7A, thereby forming the second electrode 126. Such a step is called a second electrode forming step.

In a step illustrated in FIG. 7D, an amorphous silicon film containing a trivalent element, e.g., boron, mixed therein as an impurity is formed as an impurity semiconductor film 129′ of second conductivity type by plasma CVD to cover the impurity semiconductor film 125′ of second conductivity type and the second electrode 126. Herein, the impurity semiconductor film 129′ corresponds to a second impurity semiconductor film, and the above-described step illustrated in FIG. 7D is called a film thickening step. As a result of the film thickening step, the first region of the impurity semiconductor layer can be formed by the impurity semiconductor film 125′, and the second region thereof can be formed thicker by the impurity semiconductor film 125′ and the impurity semiconductor film 129′. At that time, the impurity semiconductor film 129′ is formed in such a thickness that a total thickness of the impurity semiconductor film 129′ and the impurity semiconductor film 125′ is equal to the thickness of the second region 125b illustrated in FIG. 6A. In order to suppress reduction of light transmissivity, the useless impurity semiconductor film 129′ is then removed with the use of the mask illustrated in FIG. 7C. While the useless impurity semiconductor film 129′ is removed here, it may not be removed if the problem of reduction of light transmissivity does not occur. Furthermore, while, in this embodiment, the impurity semiconductor film 129′ is removed above the second electrode 126 in consideration of a process margin, the impurity semiconductor film 129′ may be removed such that an end of the impurity semiconductor film 129′ is aligned with and end of the second electrode 126.

In a step illustrated in FIG. 7F, the impurity semiconductor film 129′ and the impurity semiconductor film 125′ both being of second conductivity type, the semiconductor film 124′, and the impurity semiconductor film 123′ of first conductivity type are each partly removed by dry etching using the mask illustrated in FIG. 7E. With that dry etching, an array of conversion elements 12 is separated for each pixel. As a result, the impurity semiconductor layer 129, the impurity semiconductor layer 125, the semiconductor layer 124, the impurity semiconductor layer 123, and the second electrode 126 are formed on each of the plural first electrodes 122.

### Third Embodiment

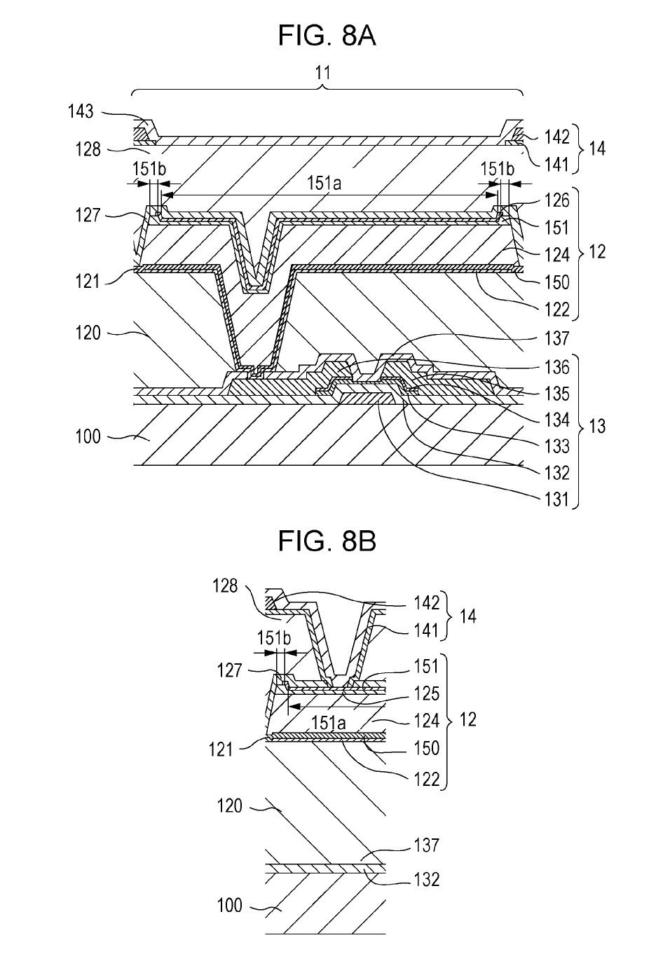

The structure of one pixel in a detection device according to a third embodiment of the present disclosure will be described below with reference to FIGS. 8A and 8B. FIG. 8A is a schematic sectional view taken along a line corresponding to the line IB-IB in FIG. 1A, and FIG. 8B is a schematic sectional view taken along a line corresponding to the line IC-IC in FIG. 1A.

In the third embodiment, an MIS photoelectric conversion element is used as the conversion element 12 instead of the PIN photodiode in the first embodiment. In more detail, the conversion element 12 includes a first electrode 122, an insulating layer 150, a semiconductor layer 124, an impurity semiconductor layer 151 of first conductivity type, and a second electrode 126, which are successively formed on the first interlayer insulating layer 120 in the mentioned order from the first interlayer insulating layer side. As in the impurity semiconductor layer 125 in the first embodiment, the impurity semiconductor layer 151 has a larger thickness in its second region 151b than in its first region 151a. Herein, the insulating layer 150 disposed between the first electrode 122 and the semiconductor layer 124 is not separated per the conversion element 12 and is disposed to extend over the plural conversion elements 12. Therefore, the insulating member 121 in the first embodiment is not used in the third embodiment.

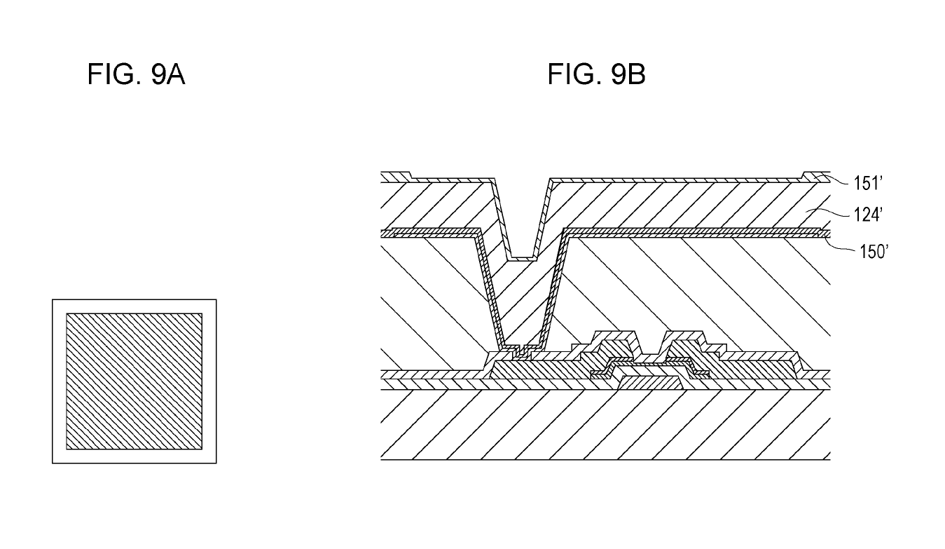

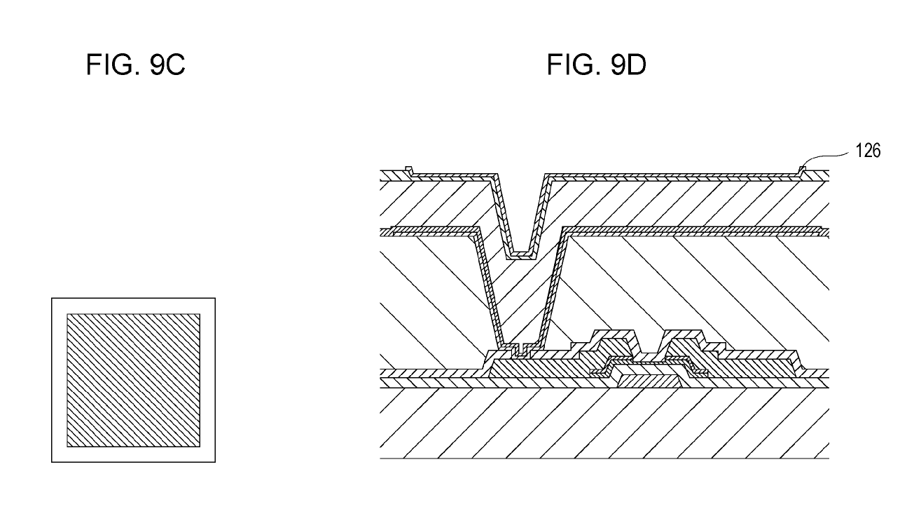

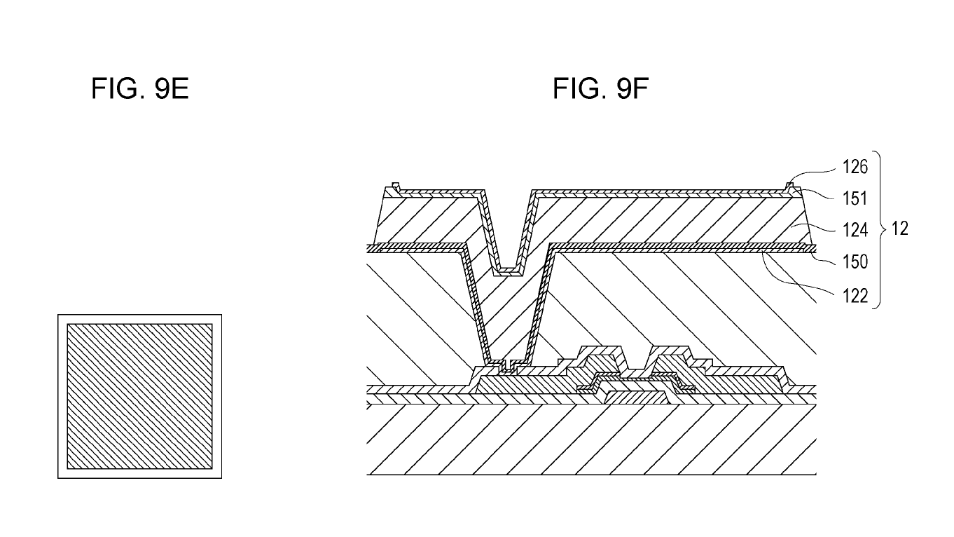

A method of manufacturing the detection device according to the third embodiment will be described below with reference to FIGS. 9A to 9F. Description of the same steps as those in the first embodiment is omitted here. More specifically, the steps illustrated in FIGS. 2B and 2D and FIGS. 4B, 4C, 4E, 4F, 4H and 4I are in common to the first embodiment and the third embodiment. FIGS. 9A, 9C and 9E are schematic plan views of the mask patterns for photomasks (masks) used in relevant steps, and FIGS. 9B, 9D and 9F are schematic sectional views in relevant steps, each taken along a line corresponding to the line IB-IB in FIG. 1A.

In a step illustrated in FIG. 9B subsequent to the step illustrated in FIG. 2D, the insulating layer 150 made of a silicon nitride film is formed by plasma CVD to cover the first interlayer insulating layer 120 and the first electrode 122. Then, a semiconductor film 124′ made of an amorphous silicon film and an amorphous silicon film containing a pentavalent element, e.g., phosphorus, mixed therein as an impurity and serving as an impurity semiconductor film 151′ of first conductivity type are successively formed in the mentioned order by plasma CVD. Herein, the impurity semiconductor film 151′ of first conductivity type is formed in the same thickness as that of the second region 151b in FIG. 8A. The above-described step illustrated in FIG. 9B is called a film forming step. Then, a region of the impurity semiconductor film 151′ of first conductivity type, becoming a first region thereof, is partly removed and thinned with the use of the mask illustrated in FIG. 9A such that the relevant region has the same thickness as that of the first region 151a in FIG. 8A. Such a step is called a film thinning step. With the film thinning step, the first region and the second region, which is thicker than the first region and which has lower sheet resistance than the first region, can be formed in the impurity semiconductor film 151′ becoming the impurity semiconductor layer 151.

In a step illustrated in FIG. 9D, an electroconductive film, e.g., a transparent electroconductive oxide film, is formed by sputtering to cover the impurity semiconductor film 151′ of first conductivity type. Then, the transparent electroconductive oxide film is partly removed by wet etching using the mask illustrated in FIG. 9C, thereby forming the second electrode 126. Such a step is called a second electrode forming step.

In a step illustrated in FIG. 9F, the impurity semiconductor film 151′ of first conductivity type and the semiconductor film 124′ are each partly removed by dry etching using the mask illustrated in FIG. 9E. With that dry etching, an array of conversion elements 12 is separated for each pixel. As a result, the insulating layer 150, the semiconductor layer 124, the impurity semiconductor layer 151, and the second electrode 126 are formed on each of the plural first electrodes 122. At that time, the insulating layer 150 is not entirely removed, and a part of the insulating layer 150 remains as it is. The above-described pixel separation by the dry etching is effectuated on the insulating member 150. Accordingly, the insulating member 150 functions as an etching stop layer, whereby the first interlayer insulating layer 120 is avoided from being exposed to species used in the dry etching and the surrounding layers can be prevented from being contaminated by the organic insulating material.

### Fourth Embodiment

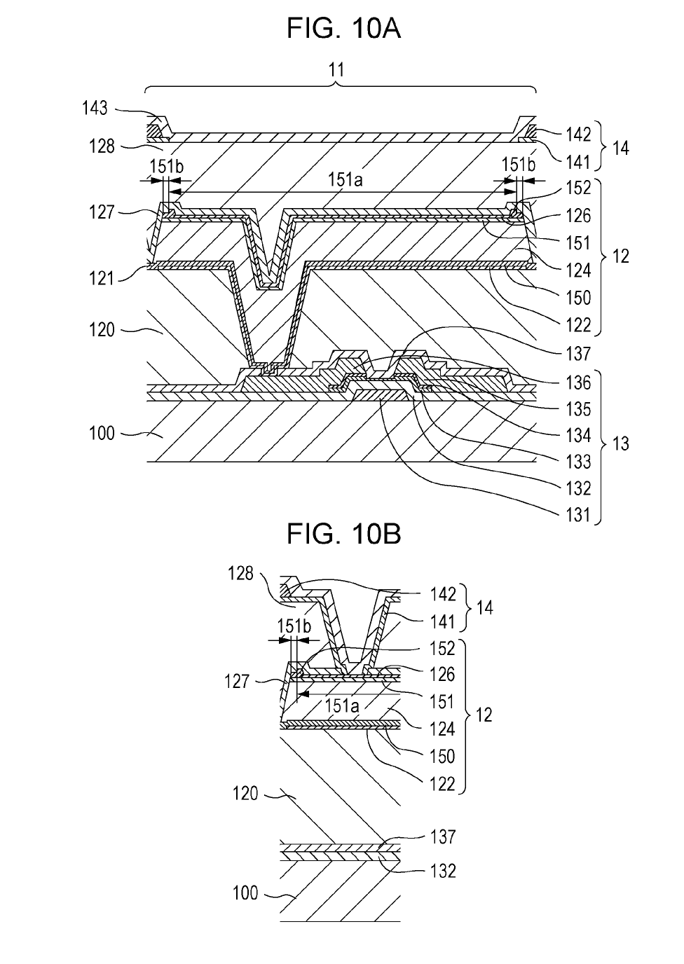

The structure of one pixel in a detection device according to a fourth embodiment of the present disclosure will be described below with reference to FIGS. 10A and 10B. FIG. 10A is a schematic sectional view taken along a line corresponding to the line IB-IB in FIG. 1A, and FIG. 10B is a schematic sectional view taken along a line corresponding to the line IC-IC in FIG. 1A.

In the fourth embodiment, an MIS photoelectric conversion element is used as the conversion element 12 instead of the PIN photodiode in the second embodiment. In more detail, the conversion element 12 includes a first electrode 122, an insulating layer 150, a semiconductor layer 124, an impurity semiconductor layer 151 of first conductivity type, and a second electrode 126, which are successively formed on the first interlayer insulating layer 120 in the mentioned order from the first interlayer insulating layer side. To make a second region 151b of an impurity semiconductor layer have a larger thickness than a first region 151a thereof, the second region 151b is made up of the impurity semiconductor layer 151 and an impurity semiconductor layer 152. The impurity semiconductor layer 152 is an impurity semiconductor layer of first conductivity type, i.e., having the same conductivity type as the impurity semiconductor layer 151 of first conductivity type. Moreover, the impurity semiconductor layer 152 is disposed on the second electrode 126 such that the second electrode 126 is sandwiched between the impurity semiconductor layer 152 and the impurity semiconductor layer 151. Herein, the insulating layer 150 disposed between the first electrode 122 and the semiconductor layer 124 is not separated per the conversion element 12 and is disposed to extend over the plural conversion elements 12. Therefore, the insulating member 121 in the second embodiment is not used in the fourth embodiment.

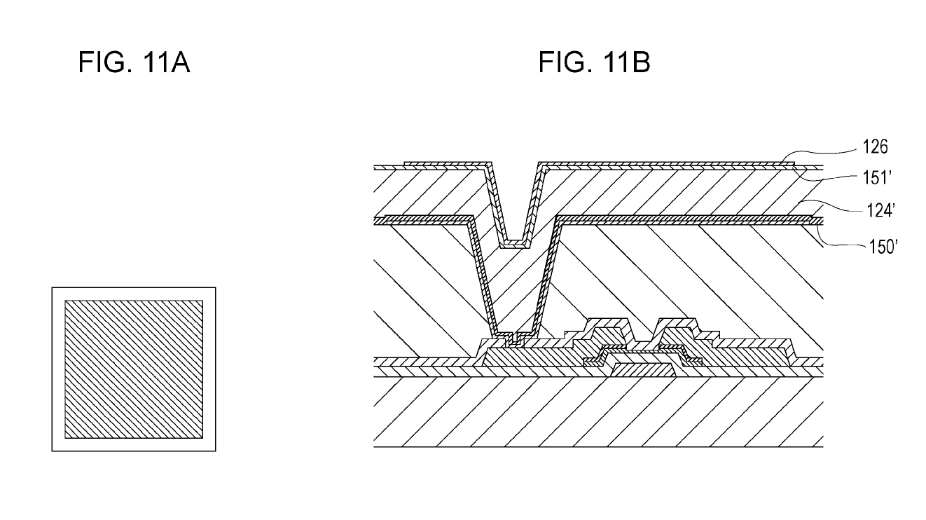

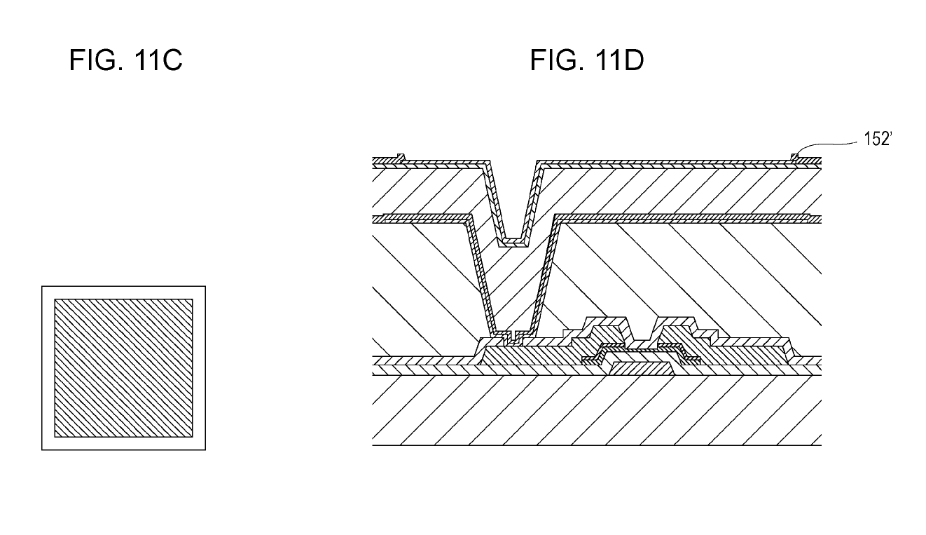

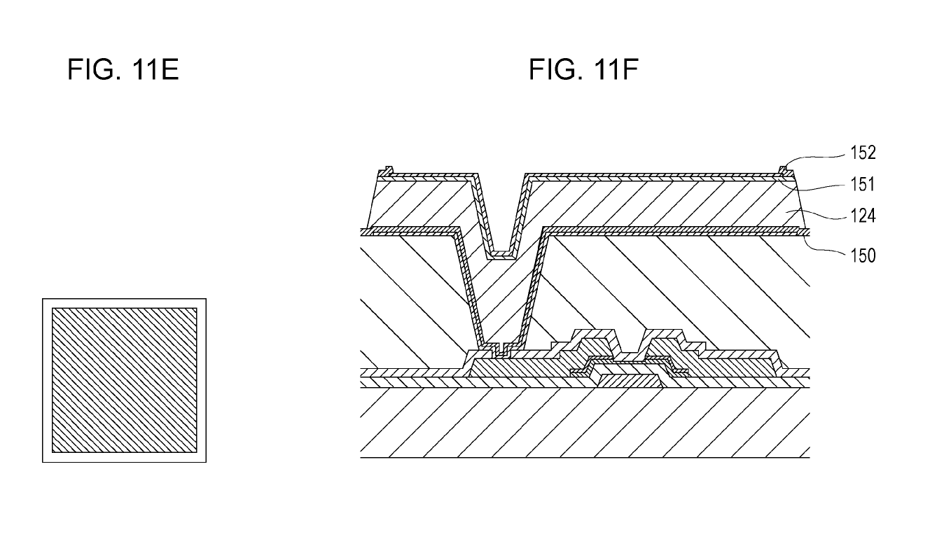

A method of manufacturing the detection device according to the fourth embodiment of the present application will be described below with reference to FIGS. 11A to 11F. Description of the same steps as those in the first embodiment is omitted here. More specifically, the steps illustrated in FIGS. 2B, 2D and FIGS. 4B, 4C, 4E, 4F, 4H and 4I are in common to the first embodiment and the fourth embodiment. FIGS. 11A, 11C and 11E are schematic plan views of the mask patterns for photomasks (masks) used in relevant steps, and FIGS. 11B, 11D and 11F are schematic sectional views in relevant steps, each taken along a line corresponding to the line IB-IB in FIG. 1A.

In a step illustrated in FIG. 11B subsequent to the step illustrated in FIG. 2D, the insulating layer 150 made of a silicon nitride film is formed by plasma CVD to cover the first interlayer insulating layer 120 and the first electrode 122. Then, a semiconductor film 124′ made of an amorphous silicon film and an amorphous silicon film containing a pentavalent element, e.g., phosphorus, mixed therein as an impurity and serving as an impurity semiconductor film 151′ of first conductivity type are successively formed in the mentioned order by plasma CVD. Herein, the impurity semiconductor film 151′ corresponds to a first impurity semiconductor film, and the above-described step illustrated in FIG. 11B is called a film forming step. At that time, the impurity semiconductor film 151′ is formed in the same thickness as that of the first region 151a in FIG. 10A. Then, an electroconductive film, e.g., a transparent electroconductive oxide film, is formed by sputtering to cover the impurity semiconductor film 151′ of first conductivity type. The transparent electroconductive oxide film is partly removed by wet etching using the mask illustrated in FIG. 11A, thereby forming the second electrode 126. Such a step is called a second electrode forming step.

In a step illustrated in FIG. 11D, an amorphous silicon film containing a pentavalent element, e.g., phosphorous, mixed therein as an impurity is formed as an impurity semiconductor film 152′ of first conductivity type by plasma CVD to cover the impurity semiconductor film 151′ of first conductivity type and the second electrode 126. Herein, the impurity semiconductor film 152′ corresponds to a second impurity semiconductor film, and the above-described step illustrated in FIG. 11D is called a film thickening step. As a result of the film thickening step, the first region of the impurity semiconductor layer can be formed by the impurity semiconductor film 151′, and the second region thereof can be formed thicker by the impurity semiconductor film 151′ and the impurity semiconductor film 152′. At that time, the impurity semiconductor film 152′ is formed in such a thickness that a total thickness of the impurity semiconductor film 151′ and the impurity semiconductor film 152′ is equal to the thickness of the second region 151b illustrated in FIG. 10A. The useless impurity semiconductor film 152′ is then removed with the use of the mask illustrated in FIG. 11C, whereby the impurity semiconductor layer 152 of second conductivity type is formed.

In a step illustrated in FIG. 11F, the impurity semiconductor film 152′ and the impurity semiconductor film 151′ both being of first conductivity type, and the semiconductor film 124′ are each partly removed by dry etching using the mask illustrated in FIG. 11E. At that time, the insulating layer 150 is not entirely removed, and a part of the insulating layer 150 remains as it is. With that dry etching, an array of conversion elements 12 is separated for each pixel. As a result, the impurity semiconductor layer 151, the impurity semiconductor layer 152, the semiconductor layer 124, the insulating layer 150, and the second electrode 126 are formed on each of the plural first electrodes 122. The above-described pixel separation by the dry etching is effectuated on the insulating member 150. Accordingly, the insulating member 150 functions as an etching stop layer, whereby the first interlayer insulating layer 120 is avoided from being exposed to species used in the dry etching and the surrounding layers can be prevented from being contaminated by the organic insulating material.

### Fifth Embodiment

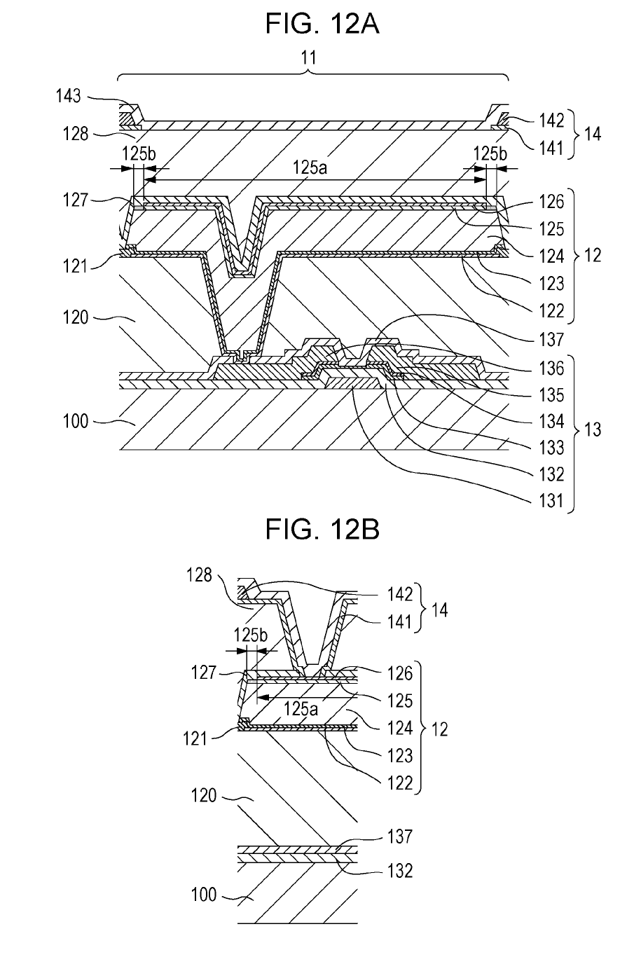

The structure of one pixel in a detection device according to a fifth embodiment of the present disclosure will be described below with reference to FIGS. 12A and 12B. FIG. 12A is a schematic sectional view taken along a line corresponding to the line IB-IB in FIG. 1A, and FIG. 12B is a schematic sectional view taken along a line corresponding to the line IC-IC in FIG. 1A.

In the fifth embodiment, as illustrated in FIGS. 12A and 12B, to make sheet resistance in a second region 125b of an impurity semiconductor layer lower than that in a first region 125a thereof, an impurity concentration in the second region 125b is set to be higher than that in the first region 125a. While the fifth embodiment is described in connection with an impurity semiconductor layer of second conductivity type in a PIN photodiode, it is also applicable to the impurity semiconductor layer 151 of first conductivity type in the MIS photoelectric conversion element described above in the third and fourth embodiments.

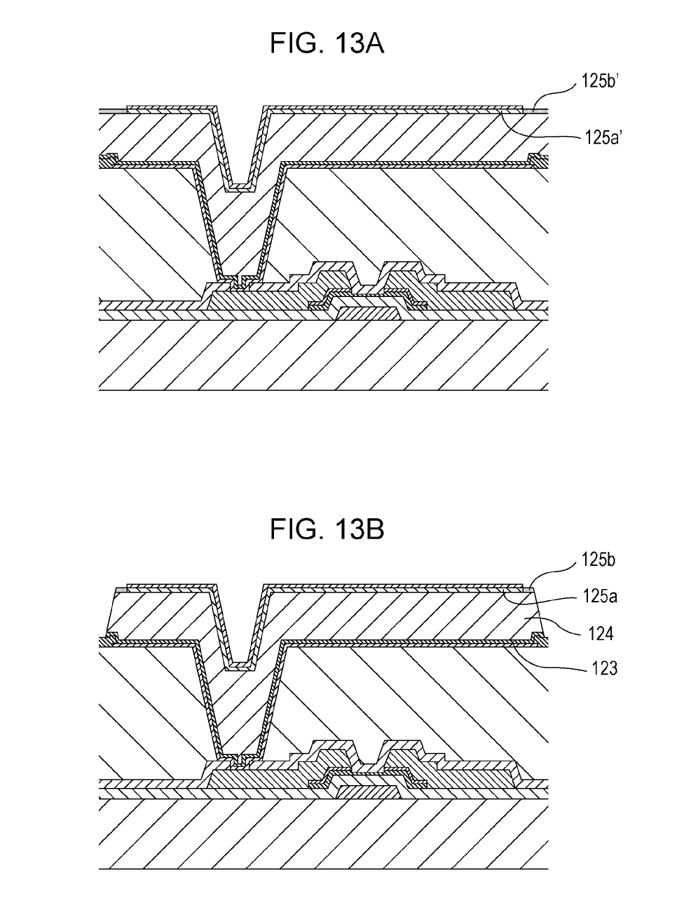

A method of manufacturing the detection device according to the fifth embodiment of the present application will be described below with reference to FIGS. 13A and 13B. Description of the same steps as those in the second embodiment is omitted here. More specifically, the steps illustrated in FIGS. 2B, 2D and 2F, FIG. 7B, and FIGS. 4B, 4C, 4E, 4F, 4H and 4I are in common to the second embodiment and the fifth embodiment. FIGS. 13A and 13B are schematic sectional views in relevant steps, each taken along a line corresponding to the line IB-IB in FIG. 1A.

In a step illustrated in FIG. 13A subsequent to the step illustrated in FIG. 7B, a trivalent element, e.g., boron, is injected as an impurity into the impurity semiconductor film 125′ with the second electrode 126 used as a mask. Thus, the impurity is further injected into a second region 125b′ of the impurity semiconductor film 125′, the second region 125b′ being not contacted with the second electrode 126, while the impurity is not further injected into a first region 125b′ of the impurity semiconductor film 125′. Thereafter, the second region 125b′ is activated by laser annealing, for example, such that an impurity concentration in the second region 125b′ is higher than that in the first region 125a′. Such a step is called a higher-impurity-concentration region forming step.

In a step illustrated in FIG. 13B, the impurity semiconductor film 125′ of second conductivity type, the semiconductor film 124′, the impurity semiconductor film 123′ of first conductivity type are each partly removed by dry etching using the mask illustrated in FIG. 7E. With that dry etching, an array of conversion elements 12 is separated for each pixel. As a result, the impurity semiconductor layer including the second region 125b having a higher impurity concentration than the first region 125a, the semiconductor layer 124, the impurity semiconductor layer 123, and the second electrode 126 are formed on each of the plural first electrodes 122.

While the first region 125a and the second region 125b have the same thickness in the fifth embodiment, the present invention is not limited to such an arrangement. The fifth embodiment is also applicable to the case where the second region 125b has a larger thickness than the first region 125a, as in the second embodiment, by stacking a plurality of impurity semiconductor layers.

### Application Embodiment

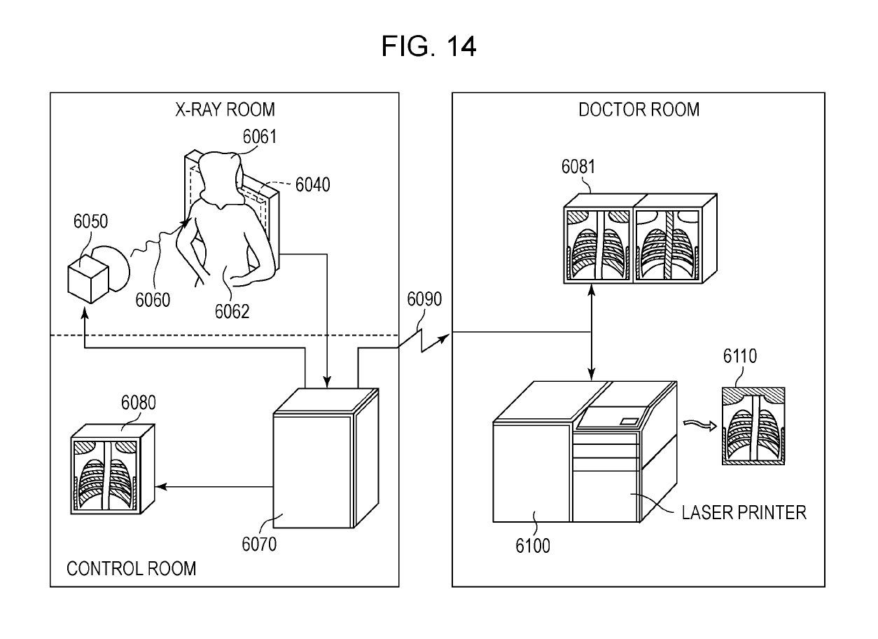

A radiation detection system using the detection device according to the embodiment of the present disclosure will be described below with reference to FIG. 14.

An X-ray 6060 emitted from an X-ray tube 6050, i.e., a radiation source, transmits through the chest 6062 of a patient or a subject 6061 and enters individual conversion elements 12 of the conversion section 3 included in a radiation detection device 6040. The X-ray having entered the conversion elements 12 contains information regarding the interior of a body of the patient 6061. Upon the incidence of the X-ray, the radiation is converted to electric charges and electrical information is obtained in the conversion section 3. The obtained electrical information is converted to digital data and is subjected to image processing in an image processor 6070, i.e., an image processing unit, such that the information can be observed on a display 6080, i.e., a display unit, in a control room.

Furthermore, the obtained information can be transferred to a remote place via a transmission processing unit, such as a telephone line 6090, and can be displayed on a display 6081, i.e., a display unit, or stored in a storage unit, e.g., an optical disk, in a doctor room at a different location. This enables a doctor at the remote place to make a diagnosis. As an alternative, the obtained information can be recorded on a film 6110, i.e., a recording medium, by a film processor 6100, i.e., a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-106882 filed May 8, 2012, which is hereby incorporated by reference herein in its entirety.

What is claimed is:

1. A detection device including conversion elements each comprising:
a first electrode disposed on a substrate;
a semiconductor layer disposed on the first electrode;
an impurity semiconductor layer disposed on the semiconductor layer and including at least a first region and a second region; and
a second electrode disposed on the first region of the impurity semiconductor layer in contact with the impurity semiconductor layer,
wherein a sheet resistance in the second region disposed at a position where the impurity semiconductor layer is not contacted with the second electrode is less than a sheet resistance in the first region.

2. The detection device according to claim 1, wherein the second region has a greater thickness than the first region.

3. The detection device according to claim 2, wherein the second region consists of plural impurity semiconductor layers stacked one above another.

4. The detection device according to claim 1, wherein the second region has a greater impurity concentration than the first region.

5. The detection device according to claim 1, further including a plurality of pixels disposed on the substrate, each of the pixels comprising the conversion element and a thin-film transistor connected to the first electrode; and
a first interlayer insulating layer disposed to cover the thin-film transistor and having a contact hole formed above the thin-film transistor,
wherein the first electrode is disposed on the first interlayer insulating layer and connected to the thin-film transistor in the contact hole.

6. The detection device according to claim 5, wherein the impurity semiconductor layer is an impurity semiconductor layer of second conductivity type, having an opposite polarity to an impurity semiconductor layer of first conductivity type disposed between the first electrode and the semiconductor layer.

7. The detection device according to claim 4, further including an insulating member disposed on the first interlayer insulating layer and made of an inorganic insulating material,
wherein the insulating member and the first electrode covers a surface of the first interlayer insulating layer.

8. The detection device according to claim 5, wherein the conversion element further comprises an insulating layer disposed between the first electrode and the semiconductor layer and covering respective surfaces of the first electrode and the first interlayer insulating layer.

9. The detection device according to claim 5, wherein, given that a width of the second region is denoted by “D”, a width of the conversion element is denoted by “P”, the sheet resistance in the second region is denoted by “Rs”, and on-resistance of the thin-film transistor is denoted by “Ron”, a following formula is satisfied:
4×Rs(D/P)≦Ron

10. A detection system comprising:
the detection device according to claim 1;
a signal processing unit configured to process a signal from the detection device;
a display unit configured to display the signal from the signal processing unit; and
a transmission processing unit configured to transmit the signal from the signal processing unit.

11. A method of manufacturing a detection device including conversion elements each comprising a first electrode disposed on a substrate, a semiconductor layer disposed on the first electrode, an impurity semiconductor layer disposed on the semiconductor layer, and a second electrode disposed on the impurity semiconductor layer in contact with the impurity semiconductor layer, the method comprising the steps of:
successively forming, on the first electrode, a semiconductor film becoming the semiconductor layer, and an impurity semiconductor film including a first region and a second region different from the first region, the impurity semiconductor film becoming the impurity semiconductor layer, in mentioned order;
forming, on the impurity semiconductor film, an electroconductive film becoming the second electrode, and removing at least a part of a region of the electroconductive film, the region contacting with the second electrode, thereby forming the second electrode; and
reducing sheet resistance in the second region to be lower than sheet resistance in the first region.

12. The method of manufacturing the detection device according to claim 11, wherein, in the successively film forming step, the impurity semiconductor film is formed in a same thickness as the second region, and
in the sheet resistance reducing step, a thickness of the first region is made less than a thickness of the second region.

13. The method of manufacturing the detection device according to claim 11, wherein, in the successively film forming step, a first impurity semiconductor film included in the impurity semiconductor film is formed in a same thickness as the first region, and
in the sheet resistance reducing step, a thickness of the second region is made thicker than a thickness of the first region by forming a second impurity semiconductor layer, which is included in the impurity semiconductor film, on a region of the first impurity semiconductor layer, the region not contacting with the second region.

14. The method of manufacturing the detection device according to claim 11, wherein, in the sheet resistance reducing step, an impurity concentration in the second region is made higher than an impurity concentration in the first region.

15. The method of manufacturing the detection device according to claim 11, wherein the first electrode is disposed in plural on the substrate, and
the method further comprises a step of partly removing a part of the impurity semiconductor film and a part of the semiconductor film such that the semiconductor layer, the impurity semiconductor layer, and the electroconductive layer are formed on each of the plural first electrodes.

16. The method of manufacturing the detection device according to claim 15, wherein the detection device includes a plurality of pixels arrayed on the substrate, each of the pixels comprising the conversion element and a thin-film transistor connected to the first electrode, and
the method further comprises the steps of:
forming a contact hole in an interlayer insulating film formed to cover the thin-film transistors, which are disposed on the substrate, at a position above each of the thin-film transistors, thereby forming a first interlayer insulating layer; and
partly removing an electroconductive film formed to cover the thin-film transistors and the first interlayer insulating layer, thereby forming the plural first electrodes.

17. The method of manufacturing the detection device according to claim 16, wherein the impurity semiconductor layer is an impurity semiconductor layer of second conductivity type, which is opposite in polarity to an impurity semiconductor layer of first conductivity type disposed between the first electrode and the semiconductor layer,
the method further comprises, between the first electrode forming step and the successively film forming step, a step of partly removing an insulating film made of an inorganic insulating material, which is formed to cover the first interlayer insulating layer made of an organic insulating material and the first electrodes, thereby forming an insulating member such that a surface of the first interlayer insulating layer is covered with the insulating member and the first electrode, and
the removing step is performed above the insulating member.

18. The method of manufacturing the detection device according to claim 16, wherein the conversion element further comprises an insulating layer disposed between the first electrode and the semiconductor layer,
in the successively film forming step, the insulating layer, the semiconductor film becoming the semiconductor layer, the impurity semiconductor film becoming the impurity semiconductor layer, and the electroconductive film becoming the second electrode are successively formed over the plural first electrodes, in mentioned order, and
in the removing step, the semiconductor layer, the impurity semiconductor layer, and the electroconductive layer are formed on each of the plural first electrodes by removing a part of the electroconductive film, a part of the impurity semiconductor layer, and a part of the semiconductor film, while the insulating layer remains.

19. The method of manufacturing the detection device according to claim 16, wherein the method further comprises the steps of:
forming a contact hole in an interlayer insulating film formed to cover the conversion element at a position above the second electrode, thereby forming a second interlayer insulating layer;
partly removing a transparent electroconductive oxide film formed to cover the second interlayer insulating layer and the second electrode, thereby forming a first electroconductive layer; and
partly removing a metal film formed to cover the first electroconductive layer and the second interlayer insulating layer, thereby forming a second electroconductive layer on the first electroconductive layer,
the second electroconductive layer being formed such that an orthographic projection of the second electroconductive layer is positioned between the two first electrodes adjacent to each other.
